(19) United States
(12) Patent Application Publication
(10) Pub. No.: US 2010/0314730 A1
(43) Pub. Date: Dec. 16, 2010

(54) Stacked hybrid interposer through silicon via (TSV) package

(75) Inventor: Shaik Labeeb, Tustin, CA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation, Irvine, CA (US)

(21) Appl. No.: 12/457,595

(22) Filed: Jun. 16, 2009

(51) Int. Cl. H01L 23/495; B32B 37/12; H01R 43/00

(52) U.S. Cl. 257/676; 156/60; 29/854; 257/E23.037

(57) ABSTRACT

An integrated circuit (IC) device is provided. The IC device includes a first die having a surface with a first pad formed thereon, a second die having a surface with a second pad formed thereon, and a substrate interposer that couples the first pad to the second pad. The substrate interposer is coupled to the surface of the first die and the surface of the second die.

### BACKGROUND OF THE INVENTION

1. Field of the Invention

The invention relates generally to the field of integrated circuit (IC) devices, and more particularly to improved coupling and low cost interconnection techniques between components included in an IC package.

2. Background Art

IC devices typically include an IC die housed in an IC package. The IC device can be coupled to a printed circuit board (PCB) to enable communication between the IC device and other devices. For example, the IC device can be a processor and can be coupled to a memory through the PCB. However, connections between the processor and the memory devices provided by the PCB may not be sufficient to enable high speed communications between them. Furthermore, each of the processor and memory devices take up space on the PCB. If one of these devices could be eliminated, space can be made available on the PCB for other devices and/or the PCB could be made smaller.

Some IC devices include multiple dies. For example, such a device can include a processor and a memory. Including the dies in the same device allows for more direct communication between the processor and memory because communications are routed through the device package rather than through the PCB. By combining the processor and memory in a single package, such a device also increases space available on the PCB for other components and/or allows for a reduction in the size of the PCB.

Existing multi-die packages require the package substrate handle routing between the dies. This tends to increase the footprint of the device and places a heavy routing burden on the package substrate. Other devices use expensive interconnection mechanisms that, while providing coupling between dies, also increase the cost of the device.

What is needed is an IC device package that provides for cost-effective interconnections between dies without placing a heavy routing burden on the package substrate.

### BRIEF SUMMARY

An integrated circuit (IC) device is provided. The IC device includes a first die having a surface with a first pad formed thereon, a second die having a surface with a second pad formed thereon, and a substrate interposer that couples the first pad to the second pad. The substrate interposer is coupled to the surface of the first die and the surface of the second die. In a further embodiment, at least one of the first and second pads is a bump pad.

In another embodiment, a method of assembling an IC device includes coupling a first die to a substrate, coupling a second die to a substrate interposer, coupling the first die to the substrate interposer, and coupling the substrate interposer to the substrate. The substrate interposer couples a first contact pad formed on a surface of the first die to a second contact pad formed on a surface of the second die. In a further embodiment, the substrate interposer is coupled to the substrate through a wire bond interconnection.

In another embodiment, an integrated circuit (IC) device includes a substrate, a first die, a substrate interposer having first and second opposing surfaces, and a second die coupled to a second surface of the substrate interposer. The first surface of the substrate interposer is coupled to an active surface of the first die. An inactive surface of the first die is coupled to a surface of the substrate. The second die is coupled to the first die through the substrate interposer.

These and other advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 illustrates an exemplary ball grid array (BGA) package.

FIG. 2 illustrates an integrated circuit (IC) package including a through silicon via.

FIG. 3 illustrates an IC package including a substrate interposer, according to an embodiment of the present invention.

FIG. 4 shows a flowchart providing example steps for assembling an IC package having a substrate interposer, according to an embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

It is noted that references in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above”, “below”, “left,” “right,” “up ”, “down”, “top”, “bottom”, etc.) used herein are for purposes of illustration only, and that practical implementations of the structures described herein can be spatially arranged in any orientation or manner.

Conventional Flip Chip Packages

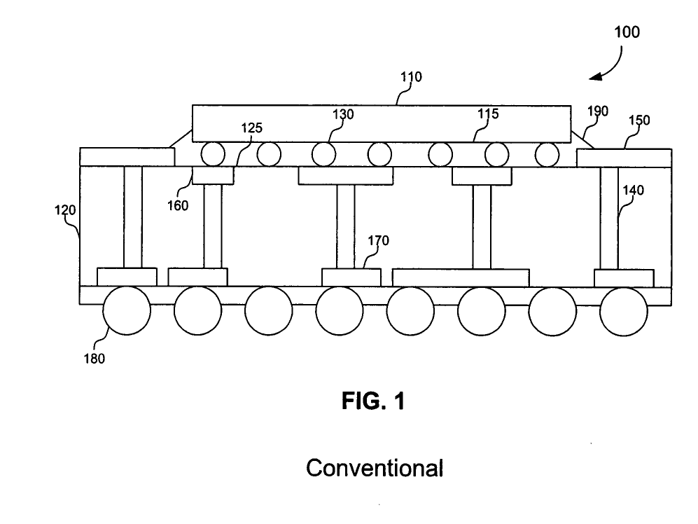

FIG. 1 shows a cross-sectional view of an exemplary flip chip ball grid array (BGA) package 100. Flip chip BGA package 100 includes a flip chip die 110 coupled to a top surface 125 of a substrate 120 via solder bumps 130. For example, flip chip BGA package 100 can be a plastic BGA (PBGA) package having a solder bumped flip chip die on a BT resin substrate, as described in J. H. Lau, “Ball Grid Array Technology”, McGraw-Hill, New York, 1995, pp. 31-33, which is incorporated by reference herein. The surface of flip chip die 110 that is in contact with solder bumps 130 can be referred to as an active surface 115 of flip chip die 110. Active surface 115 often includes power and ground distribution rails. In an embodiment, power and ground distribution rails of active surface 115 can be coupled to corresponding power and ground rails of substrate 120.

A plurality of solder bumps 130 can be distributed across active surface 115 of flip chip die 110 to respectively connect the power and ground distribution rails of flip chip die 110 to power and ground connections of substrate 120.

In the embodiment of FIG. 1, vias 140 connect solder bumps 130, traces, and/or pads 150 at top surface 125 of substrate 120 to solder balls 180 at a bottom surface of substrate 120. In an embodiment, top surface 125 of substrate 120 and the bottom surface of substrate 120 can be first and second surfaces, respectively, of substrate 120. As shown in FIG. 1, substrate 120 can include bump pads 160 and BGA contact pads 170. Bump pads 160 are connected to solder bumps 130 at top surface 125 of substrate 120. BGA contact pads 170 are connected to solder balls 180 at the bottom surface of substrate 120. Solder balls 180 can electrically connect flip chip BGA package 100 to any suitable surface having electrically conductive connections, such as a PCB.

Packages Including Through-Silicon Vias

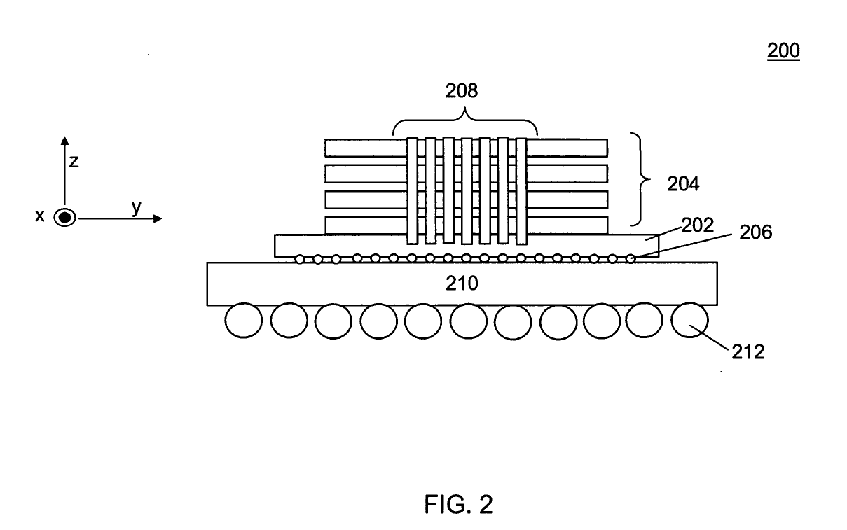

FIG. 2 shows an IC device 200 that includes an application specific integrated circuit (ASIC) die 202, a stack of memory dies 204, solder bumps 206, through-silicon vias (TSV) 208, a substrate 210, and solder balls 212. In an embodiment, ASIC die 202 is a processor. During operation, ASIC die 202 may store information on and retrieve information from dies of memory dies 204. Memory dies 204 are coupled to ASIC die 202 using TSVs 208. TSVs 208 will be described in greater detail below. Pads of ASIC die 202 (not shown in FIG. 2) are coupled to substrate 210 through solder bumps 206. Substrate 210, then, routes those pads to one or more of solder balls 212, which allow for IC device 200 to be coupled to other components through routing on a PCB.

Each of TSVs 208 travel through each of memory dies 204 and contact ASIC die 202. TSVs 208 allow for ASIC die 202 to directly communicate with memory dies 204 without the use of package substrate 210. Because memory dies 204 are directly coupled to ASIC die 202 through TSVs 208, package 200 can have a smaller foot print than other stacked packages.

Although TSVs 208 allow for high density interconnects and high speed communications between ASIC die 202 and memory dies 204, using TSVs 208 has drawbacks for IC device 200. For example, the layouts of ASIC die 202 and memory dies 204 must be adjusted to account for TSVs 208. Having to account for TSVs 208 that pass into or through a die adds another constraint to the layout process for the die, which may lead to an inefficient layout in other respects. Once IC device 200 is assembled, the use of TSVs 208 also can make testing more difficult. In particular, the high density connections that TSVs 208 provide can prevent each die in the stack from being tested individually. Moreover, IC device 200 also can have heat dissipation problems because the dies are stacked closely together without a means for spreading the heat generated by each die.

The process of forming a TSV can also be expensive, increasing the overall cost of IC device 200. Measures taken to account for the drawbacks listed above can also increase the cost of IC device 200.

Exemplary Embodiments

In embodiments described herein, there is provided an IC device including a substrate interposer that serves as a bridge between stacked dies. The inventor has found that a substrate interposer can allow dies to communicate with each other without using expensive TSVs, thereby avoiding the drawbacks of TSV packages described above.

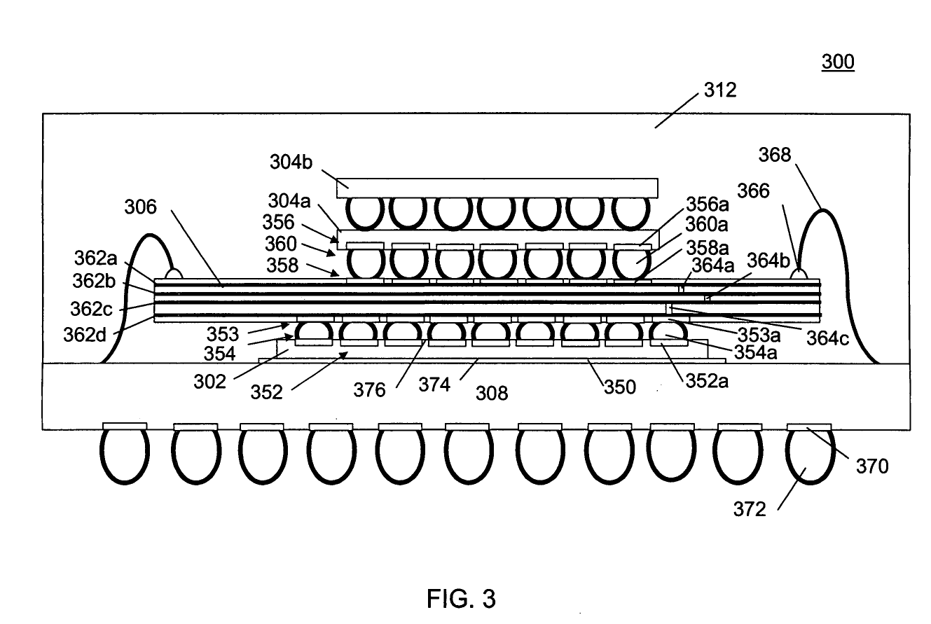

FIG. 3 shows an IC device 300, according to an embodiment of the present invention. IC device 300 includes an ASIC die 302, memory dies 304, a substrate interposer 306, a substrate 308, and an encapsulation material 312. In an embodiment, ASIC die 302 is a processor that communicates with memory dies 304. Encapsulation material 312 serves to protect the elements of IC device 300 and provide rigidity to the overall device.

As shown in FIG. 3, substrate 308 has ASIC die 302 mounted on top of it. Substrate interposer 306 is coupled to the top of ASIC die 302. Memory dies 304 are coupled to the top of substrate interposer 306.

In an embodiment, IC device 300 can include only one memory die 304, e.g., only memory die 304a. In another embodiment, e.g., when ASIC die 302 requires more memory than what memory die 304a can provide, additional memory dies can be provided. As shown in FIG. 3, IC device 300 has memory dies 304a and 304b. As would be appreciated by those skilled in the relevant art(s) based on the description herein, IC device 300 can include additional memory dies. In an embodiment, the additional memory die(s) are stacked on top of memory die 304b.

Memory dies 304 can be coupled using TSVs similar to TSVs 208 shown in FIG. 2. For example, memory dies 304 may be provided as a single device having TSV connections to a manufacturer of IC device 300.

Although ASIC die 302 and memory dies 304 are described as being an ASIC and memory dies, respectively, those skilled in art relevant art(s) will recognize, based on the disclosure herein, that ASIC die 302 and memory dies 304 can be different types of IC dies having different functionalities. In other words, the structure of IC device 300 does not depend on the functionality of ASIC die 302 and memory dies 304.

Substrate interposer 306 can be made out materials commonly used for substrates. For example, substrate interposer 306 may be made out of a plastic material, such as an epoxy or resin BT or a ceramic, such as an alumina ceramic.

As shown in FIG. 3, ASIC die 302 is coupled to substrate 308 in an inverted configuration in which an inactive surface 374 of ASIC die 302 is coupled to substrate 308. Accordingly, an active surface 376 of ASIC die 302 is coupled to the bottom surface of substrate interposer 306. Herein an active surface of a die is a surface that includes pads or other coupling means that allow the die to transmit signals to and receive signals from other devices through interconnections formed on a PCB. The inverted configuration is opposite to the configuration of ASIC die 202 and die 110, both of which are configured such that their active surfaces face their respective device substrates. As shown in FIG. 3, the inactive surface of ASIC die 302 is coupled to substrate 308 through an adhesive 350. Pads 352, formed on the active surface of ASIC die 302, are coupled to pads 353 of the bottom surface substrate interposer 306 through solder bumps 354.

Pads 356 of memory die 304a are coupled to pads 358 of substrate interposer 306 through solder bumps 360. In an embodiment, dies coupled to memory die 304a, e.g., memory die 304b, are coupled to substrate interposer 306 through memory die 304a. In an embodiment, memory dies 304a and 304b are coupled using TSVs similar to TSVs 208 that couple memory dies 204, as shown in FIG. 2.

Substrate interposer 306 serves as a bridge between ASIC die 302 and memory dies 304. As shown in FIG. 3, substrate interposer 306 includes routing features, e.g., metal layers 362a-d and vias 364a-c, that route pads 356 of memory die 304a to pads 354 of ASIC die 302. Vias 364a-c provide signal connections between layers 362a-d of substrate interposer 308.

For example, pad 356a of memory die 304a is coupled to pad 358a of substrate interposer 306 through solder bump 360a. From pad 358a, pad 356a is coupled to pad 352a of ASIC die 302 through routing on metal layers 362a-d and vias 364a-c. Other pads of memory die 304 can similarly be coupled to pads of ASIC die 302 through metal layers and vias of substrate interposer 306. Thus, the routing capabilities of substrate interposer 306 allow for communication between ASIC die 302 and memory dies 304. Furthermore, substrate interposer 306 also serves as a bridge between ASIC die 302 and substrate 308. The signal routing capabilities of substrate interposer 306 also can be used to route pads 352 to bond pads 366. From bond pads 366, wirebond connections 368 allow for interconnecting to substrate 308. In an embodiment, wirebond connections 368 are used only to couple ASIC die 302 to substrate 308, e.g., when memory dies 304 do not communicate with components outside of IC device 300. In alternate embodiments, wirebond connections 368 can be used to couple pads 352 of ASIC die 302 as well as pads 356 of memory die 304a to substrate 308. Pads 370 and solder balls 372 of substrate 308 allow for coupling to a PCB (not shown).

In an embodiment, substrate interposer 306 is specially configured to route signals. For example, metal layers 362a-d can include traces formed that enable routing between ASIC die 302, memory dies 304, and substrate 308. For example, the traces can have widths and spacing of 18 μm and 18 μm, respectively, or 15 μm and 15 μm, respectively.

Furthermore, substrate interposer 306 may be specially configured to withstand pressures exerted on it when wirebond connections 368 are formed. The inventors have found that pressures exerted on the peripheral regions of substrate interposer 306 during a wirebonding process may cause substrate interposer 306 to bounce. In an embodiment, substrate interposer 306 can include an inner metal layer (e.g., metal layer 362b or 362c) with sufficient thickness to allow for substrate interposer 306 to avoid bounce during a wire bonding process.

In another embodiment, bouncing of substrate interposer 306 can be avoided by using a stitch bond on substrate interposer 306 instead of substrate 308. As shown in FIG. 3, wirebond connections 368 are coupled to substrate interposer 306 through ball bonds 366 and to substrate 308 through stitching bonds formed on substrate 308 (not numerically referenced in FIG. 3). Using a ball bond to couple a wirebond connection to substrate interposer 306 results in significant stress being applied to substrate interposer 306. This stress can result in bouncing. To avoid this stress, stitching bonds are used to couple wirebond connections 368 to substrate interposer 306 and ball bonds, similar to ball bond 366, are used to couple wirebond connections 368 to substrate 308. Substrate 308 may be better suited to handle the stress caused by ball bonds. For example, at the stage in the assembly process where wirebonding takes place, substrate 308 still may be coupled to other substrates in a strip, and thus have greater stiffness as compared to substrate interposer 306, which is singulated before the wirebonding process.

The package shown in FIG. 3 has numerous advantages over TSV stack packages such as the one shown in FIG. 2. For example, using substrate interposer 306 to couple ASIC die 302 and memory dies 304 does not impose any requirements on the layout of ASIC die 302 and memory dies 304. In stacked TSV packages such as package 200 shown in FIG. 2, the stacked dies have to be laid out in a manner that allows for TSV connections, e.g., that allows for TSVs to pass through them. In the absence of TSVs, ASIC die 302 and memory dies 304 do not have that additional constraint on their layout.

In TSV packages, the bottom die in a stack of dies must have cross-sectional dimensions (in a plane parallel to the surface of the package substrate to which the dies are coupled) that are at least equal to the corresponding dimensions of all of the other dies in the stack. For example, in FIG. 2, ASIC die 202 must have dimensions in the x and y directions that are greater than or equal to equal to corresponding directions of memory dies 204. In contrast, there are no such requirements on ASIC die 302 of IC device 300. Thus, each die in a stack coupled using TSV connections must be at least as large as every die above it in the stack. In contrast, according to embodiments described herein, no such requirement is imposed on dies in the stack.

Furthermore, using substrate interposer 306 to provide for coupling between ASIC die 302 and memory dies 304. For example, substrate interposer may include materials that are thermally conductive. Specifically, substrate interposer 306 handles some of the routing requirements that otherwise would have been handled by substrate 308. In a further embodiment, this may allow for substrate 308 to have fewer metal layers.

Substrate interposer 306 can also serve to help spread heat generated by ASIC die 302 and memory dies 304 away from ASIC die 302 and memory dies 304 and to substrate 308 and other portions of IC device 300. Once IC device 300 is assembled, the configuration shown in FIG. 3 allows for each of ASIC die 302 and memory dies 304 to be tested individually, as opposed to dies 204 and 202 shown in FIG. 2 which can only be tested as a group.

Furthermore, including substrate interposer 306 is typically cheaper than forming TSVs. Thus, all factors being equal, IC device 300 can be cheaper than devices including TSV connections to ASIC dies, e.g., IC device 200 shown in FIG. 2.

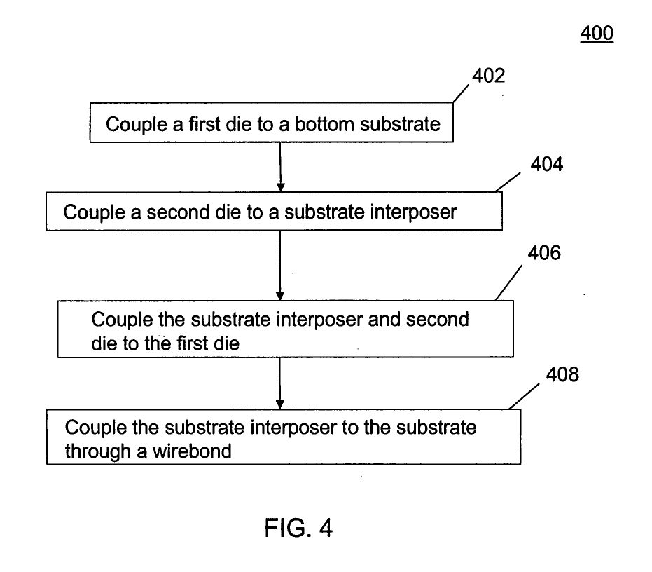

FIG. 4 shows a flowchart 400 providing example steps for assembling an IC device, according to an embodiment of the present invention. Other structural and operational embodiments will be apparent to persons skilled in the relevant art(s) based on the following discussion. The steps shown in FIG. 4 do not necessarily have to occur in the order shown. The steps of FIG. 4 are described in detail below.

In step 402, a first die is couple to a substrate. For example, ASIC die 302 is coupled to substrate 308 using an adhesive 350. In a further embodiment, the first die is coupled to the substrate in an inverted configuration. For example, as shown in FIG. 3, the inactive surface of ASIC die 302 is couple to substrate 308 through adhesive 350. The active surface is face-up and exposed at this point.

In step 404, a second die is coupled to the substrate interposer. For example, as shown in FIG. 3, pads 356 of memory die 304a are coupled to pads 358 of substrate interposer 306.

In step 406, a substrate interposer is coupled to the first die. In an embodiment, step 404 is completed before step 406. In such an embodiment, the substrate interposer is coupled to the second die in step 404 and that unit, i.e., the second die and the substrate interposer, is coupled to the first die in step 406. For example, as shown in FIG. 3, pads 352 of ASIC die 302 are coupled to pads 353 of substrate interposer 306 through solder bumps 354. Pads 352 of ASIC die 302 are coupled to pads 356 of memory die 304a through substrate interposer 306.

In step 408, the substrate interposer is coupled to the substrate. For example, as shown in FIG. 3, substrate interposer 306 is coupled to substrate 308 through bond pads 366 and wire bonds 368.

Conclusion

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. An integrated circuit (IC) device, comprising:
a first die having a surface with a first pad formed thereon;
a second die having a surface with a second pad formed thereon; and
a substrate interposer, disposed between the first and second dies, that couples the first pad to the second pad, wherein the substrate interposer is coupled to the surface of the first die and the surface of the second die.

2. The IC device of claim 1, wherein the surface of the first die is a first surface, wherein the first die has a second surface that opposes the first surface and wherein the IC device further comprises:
a substrate coupled to the second surface of the first die.

3. The IC device of claim 2, further comprising a wire bond that couples the substrate interposer to the substrate.

4. The IC device of claim 2, wherein the substrate has opposing first and second surfaces, wherein the first surface of the substrate is coupled to the second surface of the first die, and wherein the second surface of the substrate is configured to be coupled to a printed circuit board (PCB).

5. The IC device of claim 4, wherein the first surface of the substrate is coupled to the second surface of the first die through an adhesive.

6. The IC device of claim 4, wherein the substrate comprises a third pad formed on the second surface of the substrate that is configured to be coupled to the PCB.

7. The IC device of claim 6, wherein the substrate further comprises a fourth pad formed on the first surface of the substrate, the fourth pad being coupled to the third pad.

8. The IC device of claim 7, wherein the fourth pad is coupled to a bond pad located on a surface of the substrate interposer.

9. The IC device of claim 6, wherein the IC device further comprises a solder ball coupled to the third pad.

10. The IC device of claim 1, wherein the substrate interposer has opposing first and second surfaces, wherein the first surface is coupled to the surface of the first die and the second surface is coupled to the surface of the second die.

11. The IC device of claim 1, wherein a bond pad located on the first surface of the substrate interposer is coupled to at least one of the first and second pads.

12. The IC device of claim 1, wherein the substrate interposer is configured to remain substantially planar during a wire bonding process.

13. The IC device of claim 1, further comprising:
a third die coupled to the second die.

14. The IC device of claim 13, further comprising a through-silicon via that couples the third die to the second die.

15. The IC device of claim 1, further comprising an encapsulation material that encapsulates the first die, the second die, and the substrate interposer.

16. A method of assembling an IC device, comprising:
(a) coupling a first die to a substrate;
(b) coupling a second die to a substrate interposer;
(c) coupling the substrate interposer to the first die, wherein the substrate interposer couples a first contact pad formed on a surface of the first die to a second contact pad formed on a surface of the second die; and
(d) coupling the substrate interposer to the substrate.

17. The method of claim 16, wherein (a) comprises:
applying an adhesive to a surface of the substrate.

18. The method of claim 16, wherein (d) comprises:
coupling a wire bond to the substrate and the substrate interposer.

19. The method of claim 16, further comprising:
(e) coupling a third die to the second die.

20. An integrated circuit (IC) device, comprising:
a substrate;
a first die, wherein an inactive surface of the first die is coupled to a surface of the substrate;
a substrate interposer having first and second opposing surfaces, wherein the first surface of the substrate interposer is coupled to an active surface of the first die; and
a second die coupled to second surface of the substrate interposer, wherein the second die is coupled to the first die through the substrate interposer.

21. The IC device of claim 20, further comprising a wire bond that couples the second surface of the substrate interposer to the substrate.
